(19) United States
(12) Patent Application Publication
(10) Pub. No.: US 2023/0313936 A1
(43) Pub. Date: Oct. 5, 2023

(54) SOLID MATERIAL

(71) Applicant: Panasonic Intellectual Property Management Co., Ltd., Osaka (JP)

(72) Inventors: MASAKI FUJIKANE, Osaka (JP); KOUHEI TAKAHASHI, Osaka (JP); NAOKI TAMBO, Kyoto (JP); YASUYUKI NAITO, Osaka (JP)

(21) Appl. No.: 18/328,807

(22) Filed: Jun. 5, 2023

Related U.S. Application Data
(63) Continuation of application No. PCT/JP2021/045642, filed on Dec. 10, 2021.

(30) Foreign Application Priority Data
Dec. 25, 2020 (JP) 2020-217806

(51) Int. Cl. F16L 59/02

(52) U.S. Cl. CPC F16L 59/028

(57) ABSTRACT

A solid material includes a three-dimensional structure including recesses and a solid portion formed between the recesses, the three-dimensional structure adjusting a thermal conductivity of the solid material by interaction with phonons, wherein a minimum size of the solid portion between the recesses adjacent to each other in plan view of the three-dimensional structure is smaller than or equal to 100 nm, and the solid portion includes a region with a Young's modulus being smaller than or equal to 80% of a Young's modulus of a reference sample that is fabricated by using the same type of material as a material of the solid portion without forming any recesses.

### BACKGROUND

### 1. Technical Field

The present disclosure relates to a solid material.

### 2. Description of the Related Art

Until now, using a porous structure material for thermal insulation has been known. For example, a porous structure including micrometer-sized pores in a range of greater than or equal to 1 μm and smaller than or equal to 1000 μm impedes heat conduction. It is understood that, in such a porous structure, thermal insulation performance becomes higher in a material with higher porosity.

On the other hand, U.S. Patent Application Publication No. 2017/0047499, U.S. Patent Application Publication No. 2017/0069818, and Nomura et al., “Impeded thermal transport is Si multiscale hierarchical architectures with phononic crystal nanostructures”, Physical ReviewB 91, 205422 (2015) disclose periodic structures formed by through-holes and reducing the thermal conductivity of a thin film. In the disclosed periodic structures, the through-holes are regularly arrayed at a nanometer period in a range of greater than or equal to 1 nm and smaller than or equal to 1000 nm in plan view of the thin film. Those periodic structures are each one type of phononic crystal structure. That type of phononic crystal structure is a periodic structure in which a minimum unit forming an array of the through-holes is a unit lattice. The thermal conductivity of the thin film can be reduced, for example, by forming the thin film to be porous. This is because pores formed in the thin film having been made porous reduces the thermal conductivity of the thin film. On the other hand, the phononic crystal structure can reduce the thermal conductivity of a base material itself forming the thin film. Accordingly, a further reduction in the thermal conductivity is expected as compared with the case of simply forming the thin film to be porous.

### SUMMARY

The above-described techniques have room for reconsideration in terms of increasing the thermal insulation performance of a solid material.

One non-limiting and exemplary embodiment provides a technique that is advantageous from the viewpoint of increasing the thermal insulation performance of a solid material.

In one general aspect, the techniques disclosed here feature a solid material including a three-dimensional structure including recesses and a solid portion formed between the recesses, the three-dimensional structure adjusting a thermal conductivity of the solid material by interaction with phonons, wherein a minimum size of the solid portion between the recesses adjacent to each other in plan view of the three-dimensional structure is smaller than or equal to 100 nm, and the solid portion includes a region with an elastic modulus being smaller than or equal to 80% of an elastic modulus of a reference sample that is fabricated by using the same type of material as a material of the solid portion without forming any recesses.

The solid material according to the one aspect of the present disclosure is advantageous from the viewpoint of providing high thermal insulation performance.

Additional benefits and advantages of the disclosed embodiments will become apparent from the specification and drawings. The benefits and/or advantages may be individually obtained by the various embodiments and features of the specification and drawings, which need not all be provided in order to obtain one or more of such benefits and/or advantages.

### BRIEF DESCRIPTION OF THE DRAWINGS

FIG. 1 is a schematic plan view illustrating a solid material according to a first embodiment;

FIG. 2A is a cross-sectional view illustrating an example of a method of manufacturing the solid material according to the first embodiment;

FIG. 2B is a cross-sectional view illustrating the example of the method of manufacturing the solid material according to the first embodiment;

FIG. 2C is a cross-sectional view illustrating the example of the method of manufacturing the solid material according to the first embodiment;

FIG. 3 is a schematic plan view illustrating a solid material according to a second embodiment;

FIG. 4 is a schematic cross-sectional view illustrating a solid material according to a third embodiment;

FIG. 5 is a graph indicating a relation between an elastic modulus of a sample in a solid portion or a thermal conductivity of the sample and a minimum size of the solid portion of the sample;

FIG. 6 indicates load-displacement curves obtained by nanoindentation tests on a sample 1-A and a reference sample;

FIG. 7A illustrates a scanning probe microscope (SPM) image of a sample before measurement of the elastic modulus;

FIG. 7B illustrates a SPM image representing a measurement point for the elastic modulus in the sample;

FIG. 7C illustrates a SPM image representing a measurement point for the elastic modulus in the sample;

FIG. 7D illustrates a SPM image representing a measurement point for the elastic modulus in the sample;

FIG. 8A illustrates a scanning electron microscope (SEM) image of a sample;

FIG. 8B illustrates a SPM image representing a state of the measurement point for the elastic modulus in the sample before the measurement;

FIG. 8C illustrates a SPM image representing a state of the measurement point for the elastic modulus in the sample after the measurement;

FIG. 9A illustrates a SEM image of a sample;

FIG. 9B illustrates a SPM image representing a state of the measurement point for the elastic modulus in the sample before the measurement; and

FIG. 9C illustrates a SPM image representing a state of the measurement point for the elastic modulus in the sample after the measurement.

### DETAILED DESCRIPTIONS

### Underlying Knowledge Forming Basis of the Present Disclosure

In a solid material such as an insulator or a semiconductor, heat is transported mainly by lattice vibrations called “phonons”. The thermal conductivity of the solid material such as the insulator or the semiconductor is determined depending on a phonon dispersion relation in the solid material. The phonon dispersion relation includes a relation between a frequency and a wavenumber, or a band structure. In the solid material such as the insulator or the semiconductor, a frequency band in which the phonons transport heat spreads over a wide range of higher than or equal to 100 GHz and lower than or equal to 10 THz. Such a frequency band is a heat range. Thus, the thermal conductivity of the solid material is determined depending on the phonon dispersion relation in the heat range.

In a phononic crystal structure, for example, the phonon dispersion relation in a material can be adjusted with a periodic structure of through-holes. Stated another way, in the phononic crystal structure, the thermal conductivity of a material itself, for example, a base material of a thin film, can be adjusted. Especially, the thermal conductivity of the material can be greatly reduced by forming a phononic band gap (PBG) with the phononic crystal structure. The phonons cannot exist inside the PBG. Therefore, the PBG formed in match with the heat range can serve as a barrier for heat conduction. Furthermore, in a frequency band other than the band corresponding to the PBG, a gradient of a phonon dispersion curve reduces with the presence of the PBG. As a result, a phonon group velocity reduces, and a heat conduction velocity in the material falls. These matters greatly contribute to reducing the thermal conductivity of the material.

According to studies made by the inventors, reducing an elastic modulus that is considered to be a physical value specific to the material is effective in reducing the phonon group velocity. For example, it is thought that, if a technique capable of reducing the elastic modulus of the solid material made of a single type of material is developed, such a technique can give high thermal insulation performance to the solid material. However, that technique is not yet developed as far as the inventors know.

G. L. W. Cross, “Isolation leads to change”, Nature Nanotech 6, 467-468 (2011) and D. Chrobak et al, “Deconfinement leads to changes in the nanoscale plasticity of silicon”, Nature Nanotech 6, 480-484 (2011) disclose that mechanical characteristics of Si (silicon) are different between a nanometer-sized structure and a bulk state. Those papers report that, for example, Si nanoparticles with diameters of greater than or equal to 134 nm and smaller than or equal to 338 nm or Si nanoparticles with diameters of smaller than or equal to 114 nm exhibit different mechanical behaviors in relation to plastic deformation or phase transformation from those of a Si material in the bulk state.

In consideration of the above-described report examples, the inventors have conceived that, with the solid material having a predetermined structure, the elastic modulus is reduced in an elastic deformation region which is in a stage before coming into plastic deformation, and the thermal conductivity of the solid material is further affected by the reduction in the elastic modulus. The inventors have repeated trials and errors on the basis of the above-mentioned conception and have succeeded in finding the solid material according to the present disclosure.

### Summary of Embodiment According to One Aspect of Present Disclosure

The present disclosure provides a solid material comprising:
a three-dimensional structure including recesses and a solid portion formed between the recesses, the three-dimensional structure adjusting a thermal conductivity of the solid material by interaction with phonons,
wherein a minimum size of the solid portion between the recesses adjacent to each other in plan view of the three-dimensional structure is smaller than or equal to 100 nm, and
the solid portion includes a region with an elastic modulus being smaller than or equal to 80% of an elastic modulus of a reference sample that is fabricated by using same type of material as a material of the solid portion without forming any recesses.

The above-described solid material can exhibit high thermal insulation performance because the solid portion is constituted as described above.

### EMBODIMENTS OF PRESENT DISCLOSURE

Embodiments of the present disclosure will be described below with reference to the drawings. It is to be noted that any embodiments described below represent general or specific examples. Numerical values, shapes, materials, constituent elements, layout positions of and connection forms between the constituent elements, process conditions, steps, order of the steps, etc., which are described in the following embodiments, are merely illustrative, and they are not purported to limit the technique of the present disclosure. Ones of the constituent elements in the following embodiments, those ones being not stated in independent claims representing the most significant concept, are explained as optional constituent elements. Furthermore, the drawings are schematic views and are not always exactly drawn in a strict sense.

### First Embodiment

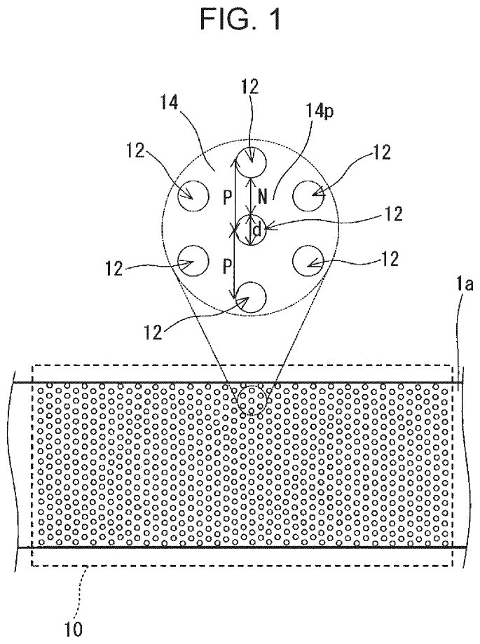

FIG. 1 is a schematic plan view illustrating a solid material 1a according to a first embodiment. The solid material 1a has a three-dimensional structure 10. The three-dimensional structure 10 includes recesses 12 and a solid portion 14. The solid portion 14 is formed between the recesses 12. The three-dimensional structure 10 adjusts the thermal conductivity of the solid material 1a by the interaction with phonons. A minimum size N of the solid portion 14 between the recesses 12 adjacent to each other in plan view of the three-dimensional structure 10 is smaller than or equal to 100 nm. The solid portion 14 includes a region 14p with an elastic modulus Ep smaller than or equal to 80% of an elastic modulus Er of a reference sample. The reference sample is a sample fabricated by using the same type of material as that of the solid portion 14 without forming any recesses. The reference sample is fabricated, for example, in a similar manner to the solid material 1a except for forming the recesses. In this specification, the elastic modulus indicates the Young's modulus.

Since the minimum size N of the solid portion 14 and the elastic modulus Ep in the region 14p are adjusted as described above, the solid material 1a is easy to exhibit high thermal insulation performance. Especially, since the elastic modulus Ep is adjusted as described above, the thermal conductivity of the solid material 1a is easy to reduce, and the solid material 1a is easy to exhibit the high thermal insulation performance. The region 14p may be positioned between the recesses 12 adjacent to each other.

The minimum size N of the solid portion 14 may be smaller than or equal to 90 nm, smaller than or equal to 85 nm, or smaller than or equal to 80 nm. The minimum size N may be smaller than or equal to 70 nm, smaller than or equal to 60 nm, smaller than or equal to 50 nm, or smaller than or equal to 40 nm. The minimum size N of the solid portion 14 is, for example, greater than or equal to 1 nm.

The elastic modulus Er of the reference sample and the elastic modulus Ep in the region 14p are determined by, for example, a nanoindentation method. Test conditions in the nanoindentation method can be provided as, for example, conditions given in EXAMPLE described later.

The elastic modulus Ep in the region 14p may be smaller than or equal to 75%, smaller than or equal to 70%, smaller than or equal to 65%, smaller than or equal to 60%, smaller than or equal to 50%, or smaller than or equal to 40% of the elastic modulus Er. The elastic modulus Ep in the region 14p may be greater than or equal to 10%, greater than or equal to 15%, greater than or equal to 20%, greater than or equal to 25%, or greater than or equal to 30% of the elastic modulus Er.

The solid material 1a is, for example, a film with a thickness of greater than or equal to 10 nm and smaller than or equal to 500 nm. As illustrated in FIG. 1, the solid material 1a has, for example, a rectangular shape in plan view.

The three-dimensional structure 10 is, for example, a phononic crystal. As illustrated in FIG. 1, the recesses 12 in the three-dimensional structure 10 are, for example, regularly arrayed in an in-plane direction.

As illustrated in FIG. 1, in plan view of the three-dimensional structure 10, the recesses 12 are arrayed at a predetermined period P. The period P is, for example, smaller than or equal to 300 nm. With that feature, the solid material 1a is easy to more reliably exhibit the high thermal insulation performance.

The period P may be smaller than or equal to 280 nm, smaller than or equal to 260 nm, smaller than or equal to 250 nm, or smaller than or equal to 200 nm. The period P may be, for example, greater than or equal to 1 nm, greater than or equal to 5 nm, or greater than or equal to 10 nm.

A shape of the recesses 12 in plan view of the three-dimensional structure 10 is not limited to a particular one. As illustrated in FIG. 1, the recesses 12 each have, for example, a circular shape in plan view of the three-dimensional structure 10.

The recesses 12 are arrayed, for example, at the period P in a particular direction. In plan view of the three-dimensional structure 10, an opening of each of the recesses 12 has a predetermined size d in a direction parallel to the particular direction. The size d and the period P satisfy a relation of, for example, d/P≥0.5. The size d is, for example, greater than or equal to 0.5 nm and smaller than or equal to 195 nm.

As illustrated in FIG. 1, in plan view of the three-dimensional structure 10, for example, a unit lattice is constituted by a regular array of the recesses 12. The unit lattice is not limited to a particular lattice. The unit lattice constituted by the regular array of the recesses 12 in plan view of the three-dimensional structure 10 is, for example, a hexagonal lattice. The unit lattice constituted by the regular array of the recesses 12 in plan view of the three-dimensional structure 10 may be a square lattice, a rectangular lattice, or a face-centered rectangular lattice.

As illustrated in FIG. 1, the phononic crystal in the three-dimensional structure 10 is, for example, a single crystal. The phononic crystal in the three-dimensional structure 10 may be, for example, a polycrystal. In this case, in plan view of the three-dimensional structure 10, the phononic crystal has domains, and the phononic crystal in each of the domains is a single crystal. Stated another way, the phononic crystal in a polycrystalline state is a complex of phononic single crystals. In the domains, the recesses 12 are regularly arrayed in different directions. In each of the domains, orientations of the unit lattices are the same. In plan view of the three-dimensional structure 10, shapes of the individual domains may be the same or different. In plan view of the three-dimensional structure 10, sizes of the individual domains may be the same or different.

When the phononic crystal in the three-dimensional structure 10 is a polycrystal, the shape of each of the domains in plan view is not limited to a particular one. The shape of each domain in plan view is, for example, a polygon including a triangle, a square, and a rectangle, a circle, an ellipse, or a combined shape including one or more of the above-mentioned shapes. The shape of each domain in plan view may be indefinite. Moreover, the number of domains included in the phononic crystal in the three-dimensional structure 10 is not limited to a particular value.

When the phononic crystal in the three-dimensional structure 10 is a polycrystal, an area of each domain in plan view of the three-dimensional structure 10 is not limited to a particular value. In plan view of the three-dimensional structure 10, each domain has an area of, for example, greater than or equal to 25P². From the viewpoint of controlling the phonon dispersion relation with the phononic crystal, the domain may have an area of greater than or equal to 25P². In the domain having a square shape in plan view, for example, the area of the domain becomes greater than or equal to 25P² by adjusting one side of the square shape to have a length of greater than or equal to 5×P.

In the three-dimensional structure 10, the recesses 12 are in the form of, for example, through-holes. With that feature, for example, when the solid material 1a is a film, a variation in physical characteristics of the solid material 1a in a thickness direction of the film is less likely to occur.

In the three-dimensional structure 10, an end of the recess 12 on an opposite side to its opening may be closed. In this case, the mechanical strength of the solid material 1a is easy to increase.

In the three-dimensional structure 10, a depth of the recess 12, namely a size of the recess 12 in the thickness direction of the film, is not limited to a particular value. A ratio of the depth of the recess 12 to the size d of the opening of the recess 12 may be, for example, greater than or equal to 1 and smaller than or equal to 10.

The solid portion 14 of the solid material 1a may be formed to be single-crystal, polycrystalline, or amorphous.

A substance included in the region 14p of the solid portion 14 is not limited to a particular type of substance. The region 14p is made of, for example, a semiconductor or an insulator. The region 14p may include silicon. When the region 14p includes silicon, the elastic modulus in the region 14p is, for example, 100 GPa. In this case, the solid material 1a can be fabricated by using silicon and is easy to have the high thermal insulation performance. The silicon may be single-crystal, polycrystalline, or amorphous.

The solid portion 14 has different elastic moduli at positions around particular at least one of the recesses 12 in plan view of the three-dimensional structure 10. The elastic moduli may be the same or different. The elastic moduli include a value for which a difference relative to a maximum value Emax of the elastic moduli is, for example, greater than or equal to 10% of the maximum value Emax. In this case, a variation in the elastic modulus at the positions around the recess 12 is easy to increase. Such a variation in the elastic modulus can effectively contribute to reducing the thermal conductivity of the solid material 1a. Therefore, the solid material 1a is easy to more reliably exhibit the high thermal insulation performance.

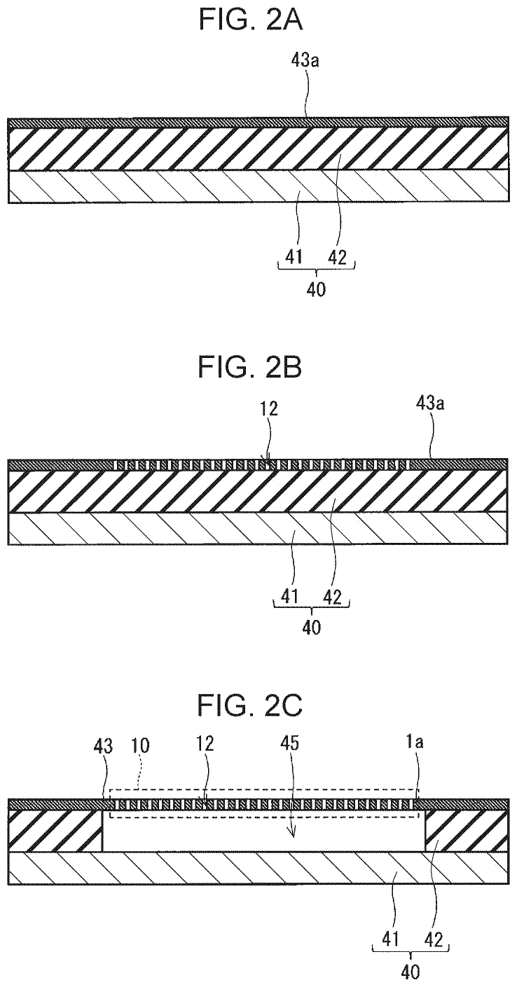

An example of a method of manufacturing the solid material 1a according to the first embodiment will be described below with reference to FIGS. 2A to 2C. The method of manufacturing the solid material 1a is not limited to the following example.

As illustrated in FIG. 2A, first, a silicon substrate 41 is prepared. Then, an insulating film 42 containing SiO₂ is formed by thermal oxidation of the silicon substrate 41 on one principal surface side in a thickness direction of the silicon substrate 41. A base substrate 40 is obtained as described above. Then, a beam layer 43a is formed on the insulating film 42. The beam layer 43a can be formed by any of known thin film formation methods such as a chemical vapor deposition (CVD) method. A material forming the beam layer 43a is not limited to a particular one. The material forming the beam layer 43a is, for example, a material allowing the beam layer 43a to partially change into a first region 13a and a second region 13b (described later) with doping, for example. Note that the influence of whether or not the doping is performed upon both the elastic modulus in the region 14p and the elastic modulus of the reference sample is small enough to be negligible. A thickness of the beam layer 43a is not limited to a particular value. The thickness of the beam layer 43a is, for example, greater than or equal to 10 nm and smaller than or equal to 500 nm. A SOI wafer may be used as a member including the base substrate 40 and the beam layer 43a.

Then, as illustrated in FIG. 2B, the recesses 12 are formed in the beam layer 43a to be regularly arrayed in plan view. When the period P of the array of the recesses 12 is greater than or equal to 100 nm and smaller than or equal to 200 nm, the recesses 12 may be formed by, for example, an electron beam lithography. When the period P of the array of the recesses 12 is greater than or equal to 1 nm and smaller than or equal to 100 nm, the recesses 12 may be formed by, for example, a block copolymer lithography. The block copolymer lithography is a method that is advantageous in fabricating, for example, the phononic crystal in the polycrystalline state in the three-dimensional structure 10.

Then, as illustrated in FIG. 2C, photolithography and selective etching are performed on the beam layer 43a and the insulating film 42. As a result, the solid material 1a in the form of a film is obtained. In addition, a cavity 45 is formed under the solid material 1a, and a beam 43 is obtained. The beam 43 is positioned to lie over the cavity 45 in a doubly supported state. Both ends of the beam 43 are connected to, for example, side surfaces of the cavity 45. Since the cavity 45 is formed, the solid material 1a is apart from the base substrate 40. Conditions for the selective etching are adjusted, for example, such that the recesses 12 are formed as through-holes. Thus, the recesses 12 are held in communicated with the cavity 45.

The elastic modulus of the solid material 1a in the region 14p can be determined, for example, by performing a nanoindentation test on a location corresponding to the region 14p in the state illustrated in FIG. 2B. In the state illustrated in FIG. 2B, the recesses 12 are formed in the beam layer 43a, and the whole of the beam layer 43a is held in contact with the base substrate 40. Alternatively, the elastic modulus in the region 14p may be determined by cutting out part of the solid material 1a illustrated in FIG. 2C to obtain a sample, and by performing the nanoindentation test on the region 14p in a state in which the sample is fixed to a substrate such as a silicon substrate.

### Second Embodiment

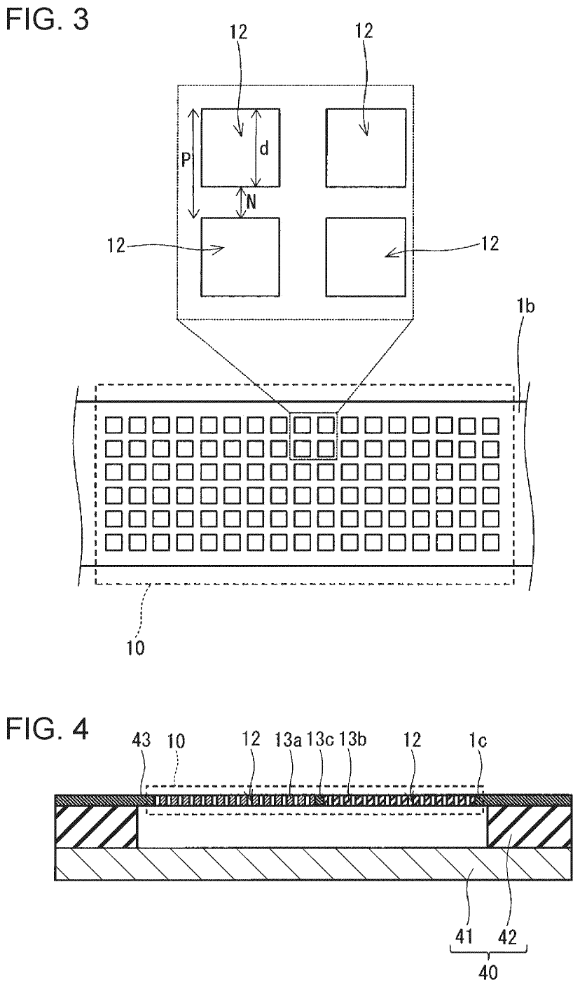

FIG. 3 is a plan view illustrating a solid material 1b according to a second embodiment. The solid material 1b is constituted in a similar way to the solid material 1a except for a point specifically described below. The same or corresponding constituent elements of the solid material 1b as or to those of the solid material 1a are denoted by the same reference signs, and detailed description of those constituent elements is omitted. The above description of the solid material 1a is also applied to the solid material 1b insofar as there are no technical contradictions.

As illustrated in FIG. 3, the recesses 12 in the solid material 1b each have a rectangular shape in plan view of the three-dimensional structure 10. With that feature, for example, when the solid material 1b has a rectangular shape in plan view of the three-dimensional structure 10, the recesses 12 are easy to arrange over a wide region.

### Third Embodiment

FIG. 4 is a cross-sectional view illustrating a solid material 1c according to a third embodiment. The solid material 1c is constituted in a similar way to the solid material 1a except for a point specifically described below. The same or corresponding constituent elements of the solid material 1c as or to those of the solid material 1a are denoted by the same reference signs, and detailed description of those constituent elements is omitted. The above description of the solid material 1a is also applied to the solid material 1c insofar as there are no technical contradictions.

As illustrated in FIG. 4, in the solid material 1c, the three-dimensional structure 10 includes a first region 13a, a second region 13b, and a third region 13c. The third region 13c is, for example, a region joining the first region 13a and the second region 13b to each other. The solid material 1c can be fabricated, for example, by performing doping on the beam 43 that is formed of the solid material 1a fabricated as described above. The solid material 1c may be fabricated in a similar manner to the solid material 1a except for performing the doping on a region of the beam layer 43a corresponding to the beam 43 in the state illustrated in FIG. 2A. In this case, a reference sample is obtained by performing the doping under the same conditions as those for the doping to fabricate the solid material 1c.

The first region 13a and the second region 13b are formed of, for example, semiconductors of different conductivity types. The first region 13a may have a conductivity type opposite to that of the second region 13b. The conductivity type of the semiconductor can be adjusted by doping. For example, the first region 13a may be formed of a p-type semiconductor, and the second region 13b may be formed of an n-type semiconductor. The first region 13a and the second region 13b can be each formed, for example, by performing the doping on the beam 43 made of single-crystal silicon. A processing technique for the single-crystal silicon is established. From that point of view, this example is superior in manufacturability.

The first region 13a has a first Seebeck coefficient. The second region 13b has, for example, a second Seebeck coefficient different from the first Seebeck coefficient. The first region 13a, the second region 13b, and the third region 13c form, for example, a thermocouple element. A difference between the first Seebeck coefficient and the second Seebeck coefficient is not limited to a particular value. The difference is, for example, greater than or equal to 10 μV/K. Note that the Seebeck coefficient in this specification indicates a value at 25° C.

### Example

The solid material according to this embodiment will be described in more detail below with reference to EXAMPLE. However, the solid material according to this embodiment is not limited to the forms described in the following EXAMPLE.

### Fabrication of Samples for Measurement of Elastic Modulus

A substrate including a silicon substrate, an insulating film, and a beam layer was prepared. The substrate was fabricated by a Separation by Implanted Oxygen (SIMOX) method. The insulating film was formed by thermal oxidation of the silicon substrate on one principal surface side and contained SiO₂. The beam layer was a thin film of single-crystal silicon and had a thickness of 100 nm. The insulating film was formed between the silicon substrate and the beam layer in a thickness direction of the silicon substrate. Then, through-holes were formed in the beam layer by the electron beam lithography or the block copolymer lithography to be regularly arrayed in an in-plane direction of the beam layer. In such a manner, samples 1-A, 2-A, 3-A, 4-A, 5-A, 6-A, and 7-A for measurement of the elastic modulus were obtained. In each of these samples, the beam layer was in close contact with the insulating film as illustrated in FIG. 2B. Table 1 lists the period P of the array of the through-holes in each of the samples, the minimum size N of a solid portion in each beam layer between the through-holes adjacent to each other in plan view of the beam layer, and the size d of an opening of each through hole in an array direction of the through-holes. A reference sample for measurement of the elastic modulus, including a flat beam layer made of single-crystal silicon, was obtained in a similar manner to the above-mentioned samples except for not forming any through-holes.

TABLE 1

| | | MINIMUM SIZE N | SIZE d OF |
|---|---|---|---|
| | | OF SOLID | OPENING OF |
| | PERIOD P | PORTION | THROUGH-HOLE |
| SAMPLE | [nm] | [nm] | [nm] |
| 1-A/1-B | 200 | 40 | 160 |
| 2-A/2-B | 300 | 60 | 240 |
| 3-A/3-B | 500 | 100 | 400 |
| 4-A/4-B | 750 | 150 | 600 |
| 5-A/5-B | 1000 | 200 | 800 |
| 6-A/6-B | 1500 | 300 | 1200 |
| 7-A/7-B | 2000 | 400 | 1600 |

### Measurement of Elastic Modulus

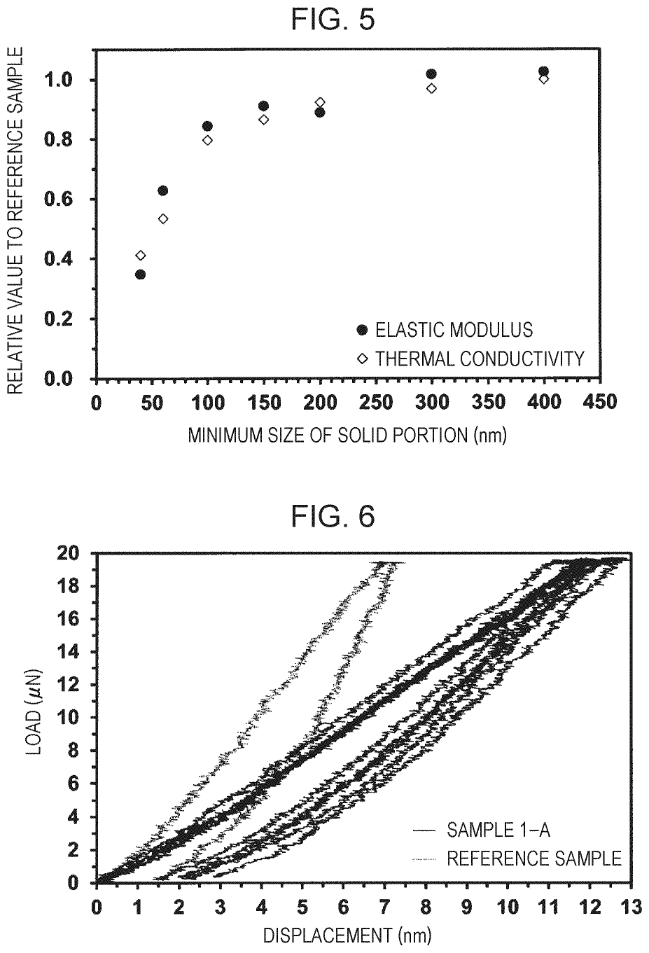

Nanoindentation tests were performed at particular positions in surfaces of the beam layers of the above-described samples 1-A, 2-A, 3-A, 4-A, 5-A, 6-A, and 7-A for measurement of the elastic modulus and the reference sample for measurement of the elastic modulus. The elastic moduli at the particular positions in the surfaces of the beam layers of the individual samples were determined based on results of the tests. In each of the nanoindentation tests, a diamond indenter was used. A tip of the diamond indenter was machined to have a curvature radius of 40 nm. In the nanoindentation test, the diamond indenter was pushed into the surface of the beam layer such that a load was increased up to a maximum value of 20 μN in 5 seconds under a load control mode. Then, after holding the load at the maximum value of 20 μN for 5 seconds, the load was released while it was gradually reduced to 0 μN in 5 seconds. An environment temperature in the nanoindentation test was adjusted to 27° C. FIG. 5 indicates a measurement result of the elastic modulus for each of the samples. In FIG. 5, the elastic modulus at the particular position in the surface of the beam layer of each sample is indicated as a relative value to a value of the single-crystal silicon forming the beam layer of the reference sample for measurement of the elastic modulus. FIG. 6 indicates load-displacement curves obtained by the nanoindentation tests on the sample 1-A for measurement of the elastic modulus and the reference sample for measurement of the elastic modulus. More specifically, FIG. 6 indicates load-displacement curves obtained by the nanoindentation tests made at five positions of the sample 1-A for measurement of the elastic modulus. FIG. 6 further indicates a load-displacement curve obtained by the nanoindentation test made at one position of the reference sample for measurement of the elastic modulus.

### Fabrication of Samples for Measurement of Thermal Conductivity

Samples 1-B, 2-B, 3-B, 4-B, 5-B, 6-B, and 7-B for measurement of thermal conductivity were fabricated, respectively, by performing selective etching on the samples 1-A, 2-A, 3-A, 4-A, 5-A, 6-A, and 7-A for measurement of the elastic modulus. With the selective etching, the beam was formed from each beam layer, and the cavity was formed by partly removing the insulating film. In each of those samples, the beam was positioned in a doubly supported state with respect to the silicon substrate as illustrated in FIG. 2C. A reference sample for measurement of thermal conductivity was also fabricated by performing selective etching on the reference sample for measurement of the elastic modulus and by forming the beam and the cavity in a similar manner.

### Measurement of Thermal Conductivity

The thermal conductivity for each of the samples 1-B, 2-B, 3-B, 4-B, 5-B, 6-B, and 7-B for measurement of the thermal conductivity in a lengthwise direction of the beam was measured in accordance with a time-domain thermosreflectance (TDTR) method. This measurement was performed under conditions of the environment temperature of 27° C. and pressure of 0.5 Pa. The thermal conductivity of the reference sample for measurement of the thermal conductivity in a lengthwise direction of the beam was also measured in a similar manner. FIG. 5 indicates a measurement result of the thermal conductivity for each of the samples. The thermal conductivity in the lengthwise direction of the beam of each sample is indicated as a relative value to a value of the reference sample for measurement of the thermal conductivity in the lengthwise direction of the beam.

### Sample 1-C for Measurement of Elastic Modulus

A sample 1-C for measurement of the elastic modulus was fabricated in a similar manner to the sample 1-A for measurement of the elastic modulus except for adjusting the period P, the minimum size N of the solid portion of the beam layer, and the size d of the opening of the through-hole to 150 nm, 60 nm, and 90 nm, respectively.

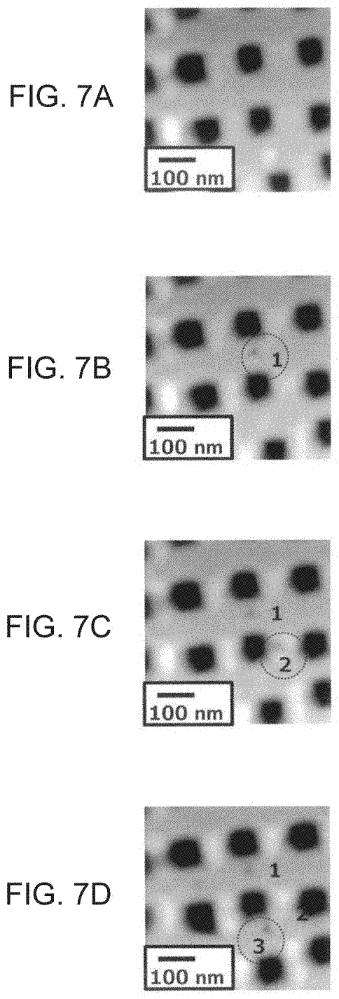

Nanoindentation tests were successively performed at positions in the solid portion of the beam layer of the sample 1-C for measurement of the elastic modulus, and the elastic modulus at each of those positions was determined. FIG. 7A illustrates a SPM image representing a surface of the sample 1-C for measurement of the elastic modulus before the nanoindentation test. In each of the nanoindentation tests, a diamond indenter was used. A tip of the diamond indenter was machined to have a curvature radius of 40 nm. The diamond indenter was pushed into the surface of the beam layer such that a load was increased up to a maximum value of 20 μN in 5 seconds under a load control mode. Then, after holding the load at the maximum value of 20 μN for 5 seconds, the load was released while it was gradually reduced to 0 μN in 5 seconds.

FIG. 7B illustrates a SPM image representing a measurement point of a first nanoindentation test in the solid portion of the beam layer. A position near a number “1” surrounded by a dotted-line circle corresponds to the measurement point. FIG. 7C illustrates a SPM image representing a measurement point of a second nanoindentation test in the solid portion of the beam layer. A position near a number “2” surrounded by a dotted-line circle corresponds to the measurement point. FIG. 7D illustrates a SPM image representing a measurement point of a third nanoindentation test in the solid portion of the beam layer. A position near a number “3” surrounded by a dotted-line circle corresponds to the measurement point. The above-mentioned measurement points are positioned around the opening of a particular one of the through-holes. The elastic moduli of the solid portion of the beam layer at the measurement points near the numbers “1”, “2”, and “3” were respectively 64.4 GPa, 52.3 GPa, and 53.8 GPa. Thus, it is understood that the elastic moduli at the positions around the particular at least one of the through-holes do not have the same value and are different more than or equal to 10% depending on locations. It is also understood that the above-mentioned unevenness in the elastic modulus of the beam layer as a continuous body contributes to reducing the thermal conductivity of the beam layer.

### Sample 1-D for Measurement of Elastic Modulus

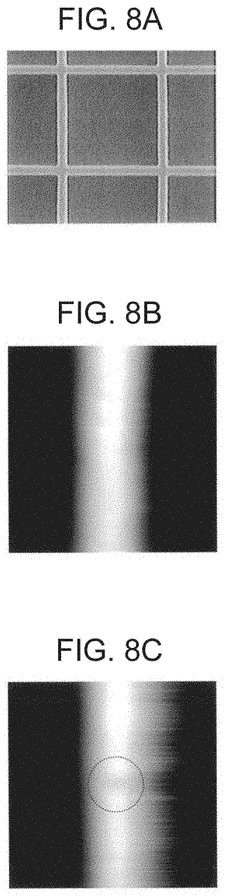

A lattice-shaped sample 1-D for measurement of the elastic modulus was fabricated in a similar manner to the sample 1-A for measurement of the elastic modulus except for adjusting the period P, the minimum size N of the solid portion of the beam layer, and the size d of the opening of the through-hole to 1297 nm, 104 nm, and 1193 nm, respectively. FIG. 8A illustrates a SEM image representing a surface of the sample 1-D for measurement of the elastic modulus.

### Sample 1-E for Measurement of Elastic Modulus

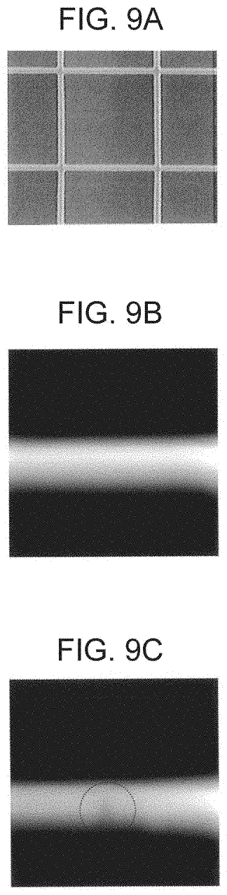

A lattice-shaped sample 1-E for measurement of the elastic modulus was fabricated in a similar manner to the sample 1-A for measurement of the elastic modulus except for adjusting the period P, the minimum size N of the solid portion of the beam layer, and the size d of the opening of the through-hole to 1259 nm, 67 nm, and 1192 nm, respectively. FIG. 9A illustrates a SEM image representing a surface of the sample 1-E for measurement of the elastic modulus.

Nanoindentation tests were performed at particular positions in the solid portions of the samples 1-D and 1-E for measurement of the elastic modulus, and the elastic modulus at each of those positions was determined. FIG. 8B illustrates a SPM image representing a region near the particular position of the sample 1-D for measurement of the elastic modulus before the nanoindentation test. FIG. 8C illustrates a SPM image representing the region near the particular position of the sample 1-D for measurement of the elastic modulus after the nanoindentation test. In FIG. 8C, the particular position is surrounded by a dotted-line circle. FIG. 9B illustrates a SPM image representing a region near the particular position of the sample 1-E for measurement of the elastic modulus before the nanoindentation test. FIG. 9C illustrates a SPM image representing the region near the particular position of the sample 1-E for measurement of the elastic modulus after the nanoindentation test. In FIG. 9C, the particular position is surrounded by a dotted-line circle. A surface observation method using the SPM is advantageous in that the position of an indentation formed by pushing the indenter in the nanoindentation test can be accurately visualized.

FIG. 5 is a graph indicating a relation between the elastic modulus of each sample in the solid portion or the thermal conductivity of each sample and the minimum size of the solid portion of the sample. In FIG. 5, the vertical axis represents the elastic modulus of each sample in the solid portion and the thermal conductivity of each sample. In FIG. 5, the elastic modulus of each sample in the solid portion and the thermal conductivity of each sample are indicated as relative values to values of the elastic modulus and the thermal conductivity of the single-crystal silicon forming the beam layer of the reference sample for measurement of the elastic modulus, respectively. In FIG. 5, the horizontal axis represents the minimum size of the solid portion of the sample. As seen from FIG. 5, a difference between the elastic modulus of the sample in the solid portion with the minimum size N of the solid portion of the beam layer being greater than or equal to 150 nm and the elastic modulus of the single-crystal silicon forming the beam layer of the reference sample for measurement of the elastic modulus is not so large. In addition, a difference between the thermal conductivity in the lengthwise direction of the beam of the sample with the minimum size N of the solid portion of the beam being greater than or equal to 150 nm and the thermal conductivity in the lengthwise direction of the beam of the reference sample for measurement of the thermal conductivity is also not so large. On the other hand, the elastic modulus of the sample in the solid portion with the minimum size N of the solid portion of the beam layer being smaller than or equal to 100 nm is lower than that of the single-crystal silicon forming the beam layer of the reference sample for measurement of the elastic modulus. For example, when the minimum size N of the solid portion of the beam layer of the sample is 40 nm, the elastic modulus of that sample in the solid portion is only 35% of that of the single-crystal silicon forming the beam layer of the reference sample for measurement of the elastic modulus. Furthermore, the thermal conductivity in the lengthwise direction of the beam of the sample with the minimum size N of the solid portion of the beam being smaller than or equal to 100 nm is lower than that in the lengthwise direction of the beam of the reference sample for measurement of the thermal conductivity. For example, when the minimum size N of the solid portion of the beam of the sample is 40 nm, the thermal conductivity in the lengthwise direction of the beam of that sample is only 41% of that in the lengthwise direction of the beam of the reference sample for measurement of the thermal conductivity. The above-mentioned results suggest that the elastic modulus having been so far regarded as a physical property value specific to a material can be controlled by adjusting the minimum size N of the solid portion. In addition, dependence of the elastic modulus in the solid portion upon the minimum size N of the solid portion and dependence of the thermal conductivity in the lengthwise direction of the beam upon the minimum size N of the solid portion exhibit a similar tendency. It is hence understood that the thermal conductivity in the lengthwise direction of the beam can be controlled by adjusting the elastic modulus in the solid portion.

As represented in FIG. 6, a maximum displacement amount in the load-displacement curve obtained from the nanoindentation test on the reference sample for measurement of the elastic modulus was only 7.2 nm. Thus, the elastic modulus of the single-crystal silicon forming the beam layer of the reference sample for measurement of the elastic modulus was 150 GPa. This value is close to that of the elastic modulus of single-crystal silicon in a bulk state. On the other hand, a maximum displacement amount in the load-displacement curve obtained from the nanoindentation test on the sample 1-A for measurement of the elastic modulus was 12.7 nm, and the elastic modulus at the particular position in the surface of the beam layer of that sample was 50 GPa. Thus, it is understood that the elastic modulus at the particular position in the surface of the beam layer of the sample 1-A for measurement of the elastic modulus is reduced to about ⅓ of the value close to the elastic modulus of the single-crystal silicon in the bulk state.

According to the results of the nanoindentation tests on the samples 1-D and 1-E for measurement of the elastic modulus, the elastic moduli in the solid portions at the particular positions in FIGS. 8C and 9C were 63.8 GPa and 34.0 GPa, respectively. It is thus understood that the elastic modulus of a material can be adjusted by microprocessing.

The above-described evaluation results have proved that the elastic modulus having been so far regarded as a physical property value specific to a material can be controlled by processing the material into the nanometer size and the thermal conductivity of the material can be controlled by adjusting the elastic modulus. Fabrication of the above-described samples has become possible for the first time by applying the material processing technique on the size order of smaller than or equal to 100 nm, the precise elastic modulus evaluation technique for materials. and the precise thermal conductivity evaluation technique. Those samples have been difficult to fabricate with the related art. The above-mentioned techniques are useful as techniques for further improving the thermal insulation performance of a thermal infrared sensor.

The solid material according to the present disclosure can be used in various applications including an application to infrared sensors.

What is claimed is:

1. A solid material comprising:
a three-dimensional structure including recesses and a solid portion formed between the recesses, the three-dimensional structure adjusting a thermal conductivity of the solid material by interaction with phonons,
wherein a minimum size of the solid portion between the recesses adjacent to each other in plan view of the three-dimensional structure is smaller than or equal to 100 nm, and
the solid portion includes a region with a Young's modulus being smaller than or equal to 80% of a Young's modulus of a reference sample that is fabricated by using same type of material as a material of the solid portion without forming any recesses.

2. The solid material according to claim 1, wherein the three-dimensional structure is a phononic crystal.

3. The solid material according to claim 1, wherein the recesses are arrayed at a period of smaller than or equal to 300 nm in the plan view of the three-dimensional structure.

4. The solid material according to claim 1, wherein the recesses are circular in the plan view of the three-dimensional structure.

5. The solid material according to claim 1, wherein the recesses are rectangular in the plan view of the three-dimensional structure.

6. The solid material according to claim 1, wherein the recesses are through-holes in the three-dimensional structure.

7. The solid material according to claim 1, wherein the region of the solid portion contains silicon, and
a Young's modulus in the region is smaller than or equal to 100 GPa.

8. The solid material according to claim 1, wherein the solid portion has different Young's moduli at positions around particular at least one of the recesses in the plan view of the three-dimensional structure, and
the Young's moduli include a value for which a difference from a maximum value of the Young's moduli is greater than or equal to 10% of the maximum value.

9. A solid material comprising:
a three-dimensional structure including recesses and a solid portion formed between the recesses, the three-dimensional structure being a phononic crystal,
wherein a minimum size of the solid portion between the recesses adjacent to each other in plan view of the three-dimensional structure is smaller than or equal to 100 nm, and
the solid portion includes a region with a Young's modulus being smaller than or equal to 80% of a Young's modulus of a reference sample that is fabricated by using same type of material as a material of the solid portion without forming any recesses.
